(19) United States
(12) Patent Application Publication
(10) Pub. No.: US 2025/0351660 A1
(43) Pub. Date: Nov. 13, 2025

(54) Organic Photodiode (OPD) and Manufacturing Method Thereof

(71) Applicant: PixArt Imaging Incorporation, Hsinchu (TW)

(72) Inventors: Hsin-Hui Hsu, Hsinchu (TW); Ping-Chun Chen, Hsinchu (TW); Chih-Ming Sun, Hsinchu (TW); Chih-Fan Hu, Hsinchu (TW)

(21) Appl. No.: 18/658,969

(22) Filed: May 8, 2024

(51) Int. Cl. H10K 30/89; H10K 30/81

(52) U.S. Cl. CPC H10K 30/89; H10K 30/81

(57) ABSTRACT

The present invention provides an organic photodiode (OPD) and a manufacturing method thereof. The OPD includes: a device, which is formed in a substrate; an interconnect structure, which is formed on the device and is connected to the device; a bottom electrode, which is formed on the interconnect structure, and is connected to a taper plate of the interconnect structure, wherein the bottom electrode is completely formed within an upper surface of the taper plate, and wherein a contact area between the bottom electrode and the taper plate is of a same order of magnitude as a pixel size, while the upper surface of the taper plate exceeds the pixel size; and an organic layer, which is formed on the bottom electrode, and is connected to the bottom electrode.

### BACKGROUND OF THE INVENTION

### Field of Invention

The present invention relates to an organic photodiode (OPD). Particularly, it relates to such organic photodiode which has a bottom electrode which is entirely formed within a vertical projection region of an upper surface of a taper plate. The present invention also relates to a manufacturing method of the organic photodiode.

### Description of Related Art

FIG. 1A shows a cross-sectional schematic diagram of a prior art organic photodiode. Organic photodiodes (OPDs) have demonstrated significant potential applications in optical imaging, sensing, and communication due to their broad photoelectric tunable characteristics, low-temperature processability, and superior mechanical flexibility. FIG. 1A shows two organic photodiodes 10. Each organic photodiode 10 includes a device 12, an interconnect structure 13, a bottom electrode 14, and an organic layer 15. The device 12 is formed in the substrate 11, and the interconnect structure 13 is formed on the device 12. The bottom electrode 14 is formed on a top conduction plug Vt of the interconnect structure 13. The organic layer 15 is formed on the bottom electrode 14. The bottom electrode 14 is ultra-thin relative to the organic layer 15 to avoid coating scattering in the layers of the organic layer 15.

Referring to FIG. 1B, which shows an image of the prior art organic photodiode captured by a transmission electron microscopy (TEM). In FIG. 1B, a top conduction plug Vt, a bottom electrode 14, and an interlayer dielectric layer ILD of the prior art organic photodiode are shown in a vertical cross-sectional view. With the bottom electrode 14 being ultra-thin compared to the organic layer 15, voids VDs are formed between the bottom electrode 14 and the top conduction plug Vt of the interconnect structure 13. The voids VDs are a result of the recess etching in the process steps that form the top conduction plug Vt. The vertical shape of the top conduction plug Vt formed by the recess etching process has a groove with a lower profile relative to the surrounding interlayer dielectric layer ILD, as indicated by the dashed line in FIG. 1B.

The voids VDs in the prior art organic photodiode 10 leads to poor contact between the bottom electrode 14 and the top conduction plug Vt beneath it, resulting in unstable electrical characteristics of the organic photodiode 10.

In view of the above, the present invention proposes an innovative organic photodiode (OPD) and a manufacturing method thereof to overcome the drawbacks in the prior art.

### SUMMARY OF THE INVENTION

From one perspective, the present invention provides an organic photodiode, comprising: a device, which is formed in a substrate; an interconnect structure, which is formed on the device and is connected to the device; a bottom electrode, which is formed on the interconnect structure, and is connected to a taper plate of the interconnect structure, wherein the bottom electrode is completely formed within an upper surface of the taper plate, and wherein a contact area between the bottom electrode and the taper plate is of a same order of magnitude as a pixel size, while the upper surface of the taper plate exceeds the pixel size; and an organic layer, which is formed on the bottom electrode, and is connected to the bottom electrode.

From another perspective, the present invention provides a manufacturing method of an organic photodiode, comprising: first, forming device in a substrate; then, forming an interconnect structure on and connected to the device; then, forming a bottom electrode on the interconnect structure and connected to a taper plate of the interconnect structure, wherein the bottom electrode is completely formed within an upper surface of the taper plate, and wherein a contact area between the bottom electrode and the taper plate is of a same order of magnitude as a pixel size, while the upper surface of the taper plate exceeds the pixel size; and then, forming an organic layer on and connected to the bottom electrode.

In one preferred embodiment, the taper plate includes a top conduction plug and a taper plate, wherein the top conduction plug is connected to a top metal layer of the interconnect structure, and the taper plate has a lower surface opposite to the upper surface, wherein the upper surface is connected to the bottom electrode and the bottom electrode is located within a vertical projection region of the upper surface, wherein the lower surface is connected to the top conduction plug.

In one preferred embodiment, an angle between a taper sidewall of the taper plate and a normal to the lower surface ranges from 0 degrees to 45 degrees.

In one preferred embodiment, a material of the bottom electrode includes at least one of the following: titanium nitride, titanium, aluminum, tantalum nitride, tantalum, chromium, silver, and gold.

In one preferred embodiment, a readout circuit is additionally formed in the substrate, wherein the readout circuit includes at least one semiconductor device and a readout interconnect structure, and the semiconductor device is electrically connected to the readout interconnect structure, and the readout circuit is coupled to the organic photodiode for reading out a photoelectric signal generated by the organic photodiode.

The objectives, technical details, features, and effects of the present invention will be better understood with regard to the detailed description of the embodiments below, with reference to the attached drawings.

### BRIEF DESCRIPTION OF THE DRAWINGS

FIG. 1A shows a cross-sectional schematic diagram of a prior art organic photodiode.

FIG. 1B shows an image of the prior art organic photodiode captured by a transmission electron microscopy (TEM).

FIG. 2 shows a cross-sectional schematic diagram of an organic photodiode according to the present invention.

FIG. 3A shows a cross-sectional schematic diagram of a bottom electrode and a taper plate according to the present invention.

FIG. 3B shows a top view schematic diagram of the bottom electrode and the taper plate according to the present invention.

FIGS. 4A-4E show schematic diagrams of process steps for manufacturing an organic photodiode according to one embodiment of the present invention.

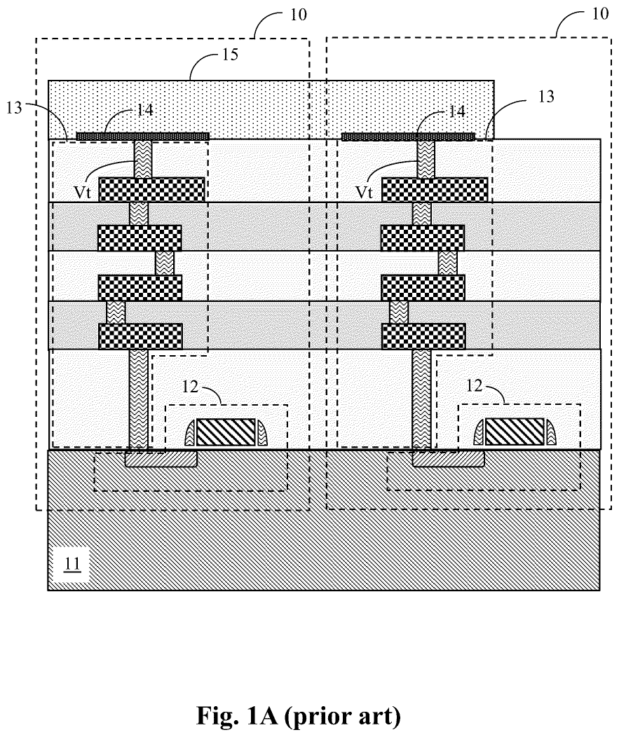

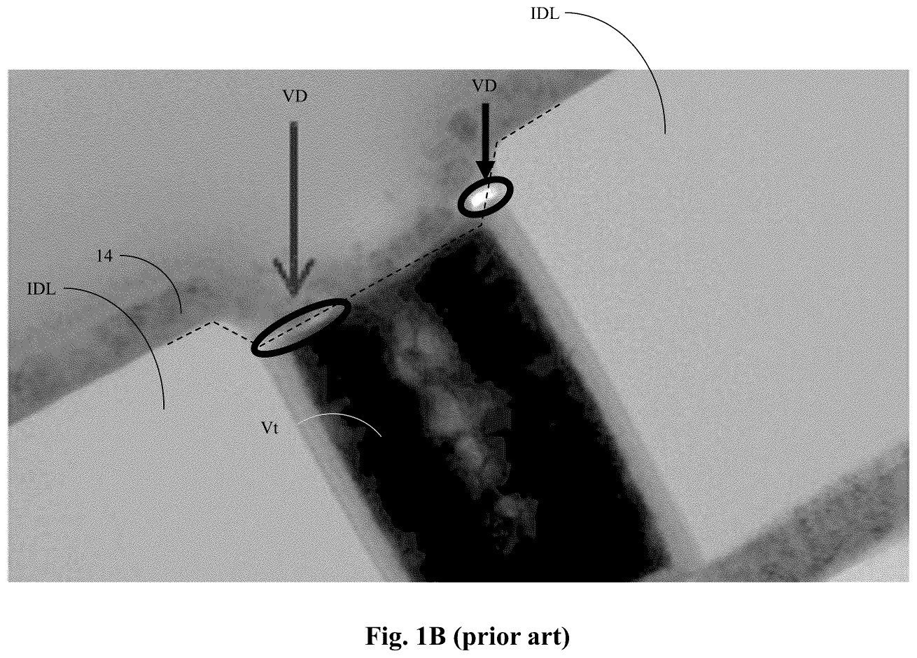

### DESCRIPTION OF THE PREFERRED EMBODIMENTS

The drawings as referred to throughout the description of the present invention are for illustration only, to show the interrelations between the regions and the process steps, but not drawn according to actual scale.

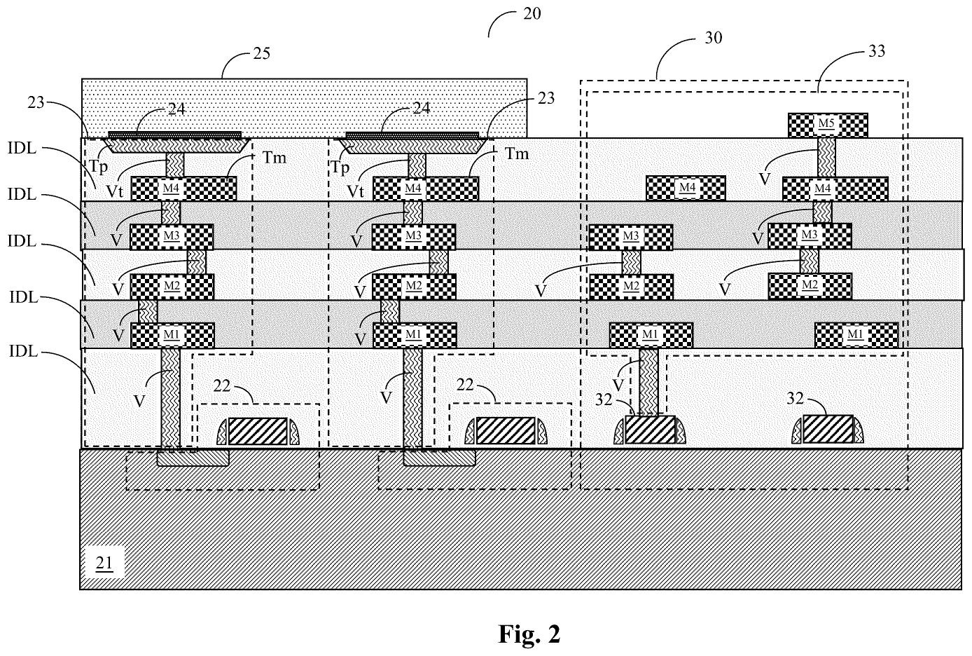

FIG. 2 shows a cross-sectional schematic diagram of an organic photodiode according to one embodiment of the present invention. As shown in FIG. 2, an organic photodiode 20 of the present invention includes: a device 22, an interconnect structure 23, a bottom electrode 24, and an organic layer 25. The device 22 is formed in the substrate 21. It should be noted that the device 22 is formed in the substrate 21, and it is not limited to being formed only inside the substrate 21; it also includes a gate structure on the substrate 21. The interconnect structure 23 is formed on the substrate 21 and is connected to the device 22. The interconnect structure 23 includes plural metal layers M1-M4 (shown as four layers in this embodiment, but according to the present invention, the number of metal layers is not limited to four) and a plurality of conduction plugs V. The conduction plugs V are electrically connected to the plural metal layers M1-M4 and the device 22 correspondingly. In addition to the connected portions among the device 22, the plural metal layers M1-M4 and the conduction plugs V, interlayer dielectric layers ILD are provided to insulate between them. A material of the plural metal layers M1-M4 includes, for example but not limited to, aluminum, copper, aluminum-copper alloy, or other conductive materials. A material of the conduction plugs V includes, for example but not limited to, tungsten, polycrystalline silicon, aluminum, copper, aluminum-copper alloy, or other conductive materials. In a preferred embodiment, the interlayer dielectric layer ILD includes a silicon dioxide layer. The bottom electrode 24 is formed on the interconnect structure 23 and is connected to a taper plate Tp of the interconnect structure 23, wherein the bottom electrode 24 is completely formed within a vertical projection region of an upper surface of a taper plate Tp of the taper plate Tp, and wherein a contact area between the bottom electrode 24 and the taper plate Tp is of a same order of magnitude as a pixel size, while the upper surface of the taper plate Tp exceeds the pixel size. The organic layer 25 is formed on the bottom electrode 24 and is connected to the bottom electrode 24.

Note that, the pixel size refers to dimensions of an individual pixel in a digital imaging device, such as a camera sensor or display. In sensors, pixel size is crucial as it affects the amount of light each pixel can capture, influencing the sensor's sensitivity and image quality. The pixel size is well known to those of ordinary skill in the art and is not elaborated here further. a projected area of the pixel size in the vertical direction is substantially equivalent to a projected area of the bottom electrode 24 in the vertical direction.

When integrating and manufacturing the organic photodiode 20 according to the present invention using CMOS processes, a readout circuit 30 is additionally formed on the substrate 21. The readout circuit 30 comprises at least one semiconductor device 32 and an interconnect structure 33. The interconnect structure 33 includes plural metal layers M1-M5 (shown as five layers in this embodiment, but according to the present invention, the number of metal layers is not limited to five) and plural conduction plugs V. The conduction plugs V are electrically connected to the plural metal layers M1-M5 and the semiconductor device 32 correspondingly. In addition to the connected portions among the device 22, the plural metal layers M1-M5 and the conduction plugs V, the interlayer dielectric layers ILD are provided for insulation. A material of the plural metal layers M1-M5 include, for example but not limited to, aluminum, copper, aluminum-copper alloy, or other conductive materials. A material of the conduction plugs V include, for example but not limited to, tungsten, polycrystalline silicon, aluminum, copper, aluminum-copper alloy, or other conductive materials. In a preferred embodiment, the interlayer dielectric layer ILD includes a silicon dioxide layer.

In this embodiment, the substrate 21 is, for example, but not limited to, a silicon substrate. As shown in FIG. 2, each of the metal layers M1-M4 of the interconnect structure 23 of the present embodiment, and each of the metal layers M1-M4 of the interconnect structure 33, are formed by a same deposition process step respectively.

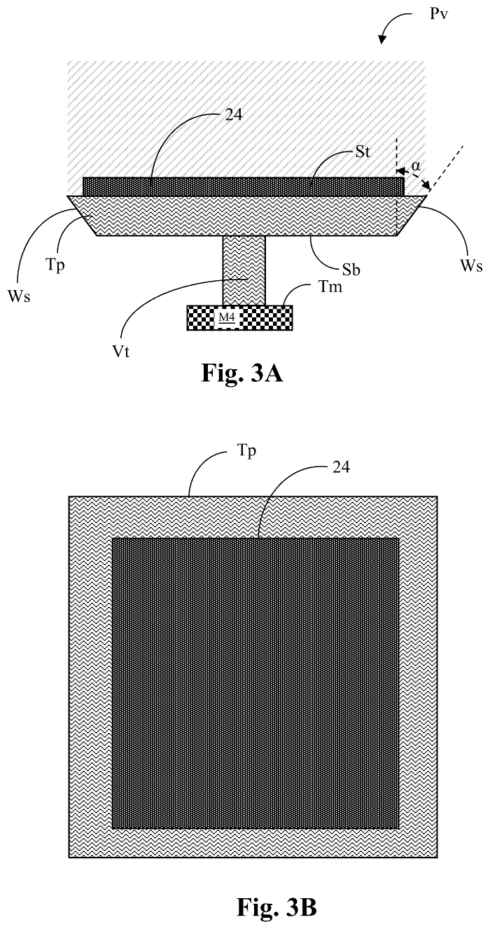

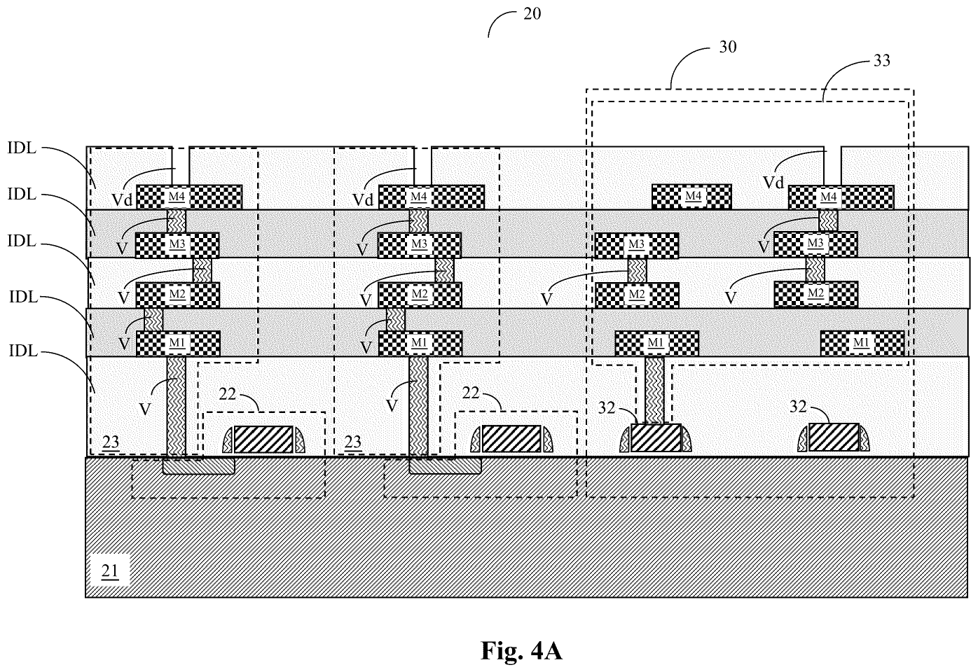

Referring to FIG. 2, compared with the prior art organic photodiode 10, in the organic photodiode 20 according to the present invention, the bottom electrode 24 is formed on the interconnect structure 23 and is connected to the taper plate Tp of the interconnect structure 23, wherein the bottom electrode 24 is completely formed within a vertical projection region of the taper plate Tp. Note that the term “vertical projection region” indicates an area covered by a projection of the taper plate Tp in a vertical direction, as shown in an area with diagonal stripes without outer boder in FIG. 3A.

According to the present invention, the bottom electrode 24 is connected to the taper plate Tp and completely located within the vertical projection region of the taper plate Tp, resolving the issue of the void formation VD between the bottom electrode 14 and the top conduction plug Vt of the interconnect structure 13, resulting in poor contact, and thus instability in the electrical characteristics of the organic photodiode 10. In other words, because the bottom electrode 24 according to the present invention is completely formed within a range covered by the projection of the taper plate Tp in a vertical direction, there is no issue of void formation VD between the bottom electrode 14 and the top conduction plug Vt as in the prior art. More specifically, in the prior art, in the CMP and/or the etching process of forming the top conduction plug Vt, the vertical shape (vertical profile) of the top conduction plug Vt formed by recess CMP and/or etching process has a lower groove relative to the surrounding interlayer dielectric layer ILD, i.e., the interlayer dielectric ILD and the top conduction plug Vt have a height difference (step height), causing the problem of void formation when the bottom electrode 14 is formed on the top conduction plug Vt in the prior art.

Note that, the top conduction plug refers to a conduction plug that, in the vertical direction, does not have any other conduction plug above it. Similarly, the top metal layer refers to a metal layer that, in the vertical direction, does not have any other metal layer above it.

In a preferred embodiment, in the organic photodiode 20, a material of the bottom electrode 24 includes at least one of the following: titanium nitride, titanium, aluminum, tantalum nitride, tantalum, chromium, silver, and gold.

Referring to FIGS. 3A and 3B, FIGS. 3A and 3B respectively show a cross-sectional schematic diagram and a top view schematic diagram of the bottom electrode 24 and the taper plate Tp and the top conduction plug Vt according to one embodiment of the present invention. In a preferred embodiment, in the organic photodiode 20, the top conduction plug Vt is connected to a top metal layer Tm of the interconnect structure 23 (in this embodiment, the metal layer M4 serves as the top metal layer Tm), and the taper plate Tp has an upper surface St and a lower surface Sb opposite to the upper surface St, wherein the upper surface St is connected to the bottom electrode 24 and the bottom electrode 24 is located within the vertical projection region of the upper surface St, and the lower surface Sb is connected to the top conduction plug Vt.

In a preferred embodiment, an angle α between a taper sidewalls Ws of the taper plate Tp and a normal to the lower surface Sb is 0 degrees to 45 degrees. Note that, the taper sidewalls Ws are sidewalls of the taper plate Tp. Note that, in one embodiment, the upper surface St and the lower surface Sb are both flattened. In another embodiment, the lower surface Sb may not be flattened. The lower surface Sb could be other shapes instead of flattened, wherein the lower surface Sb may be a rough surface, an irregular planar surface, a round surface, etc.

As shown in FIG. 3B, in the organic photodiode 20 according to the present invention, as shown in the top view, the bottom electrode 24 is completely connected to the taper plate Tp and formed within the vertical projection region of the taper plate Tp, indicating that the bottom electrode 24 is completely within the range covered by the projection of the taper plate Tp in the vertical direction.

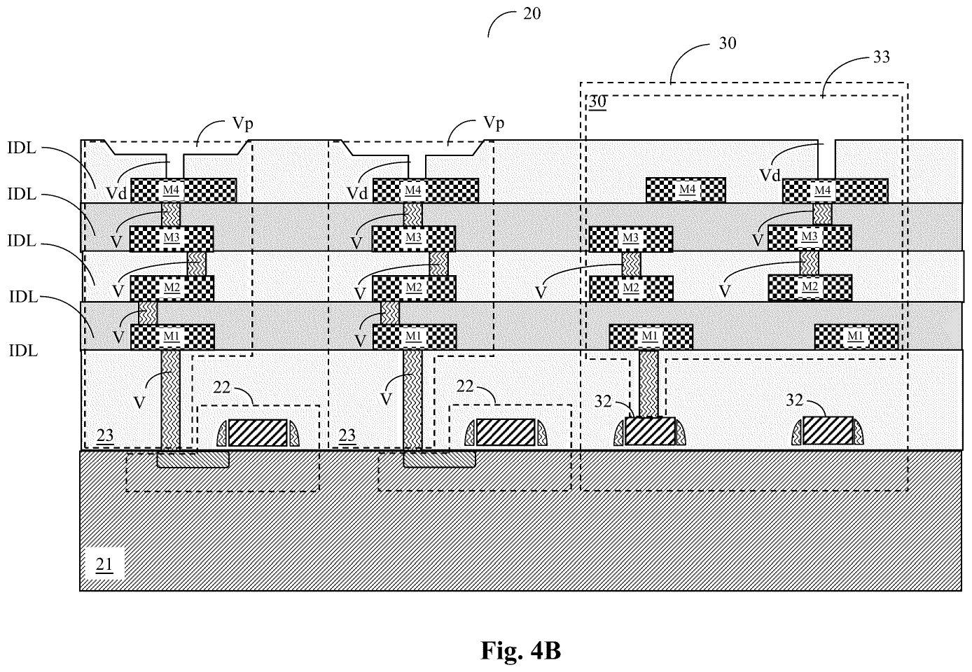

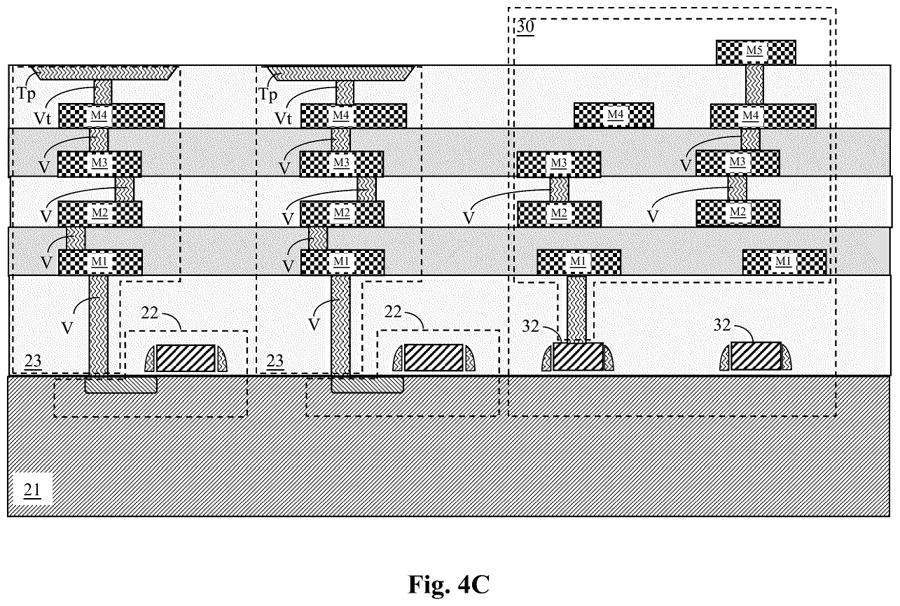

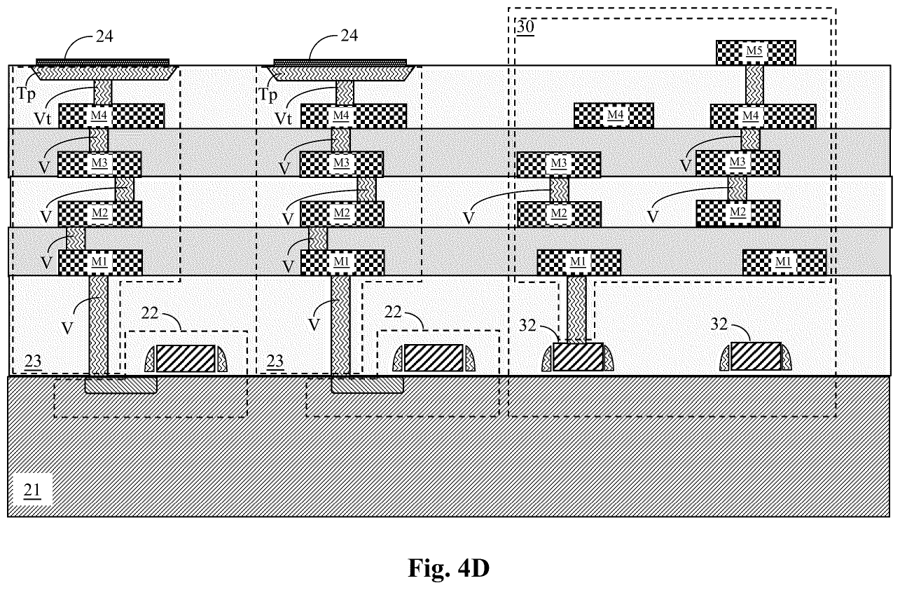

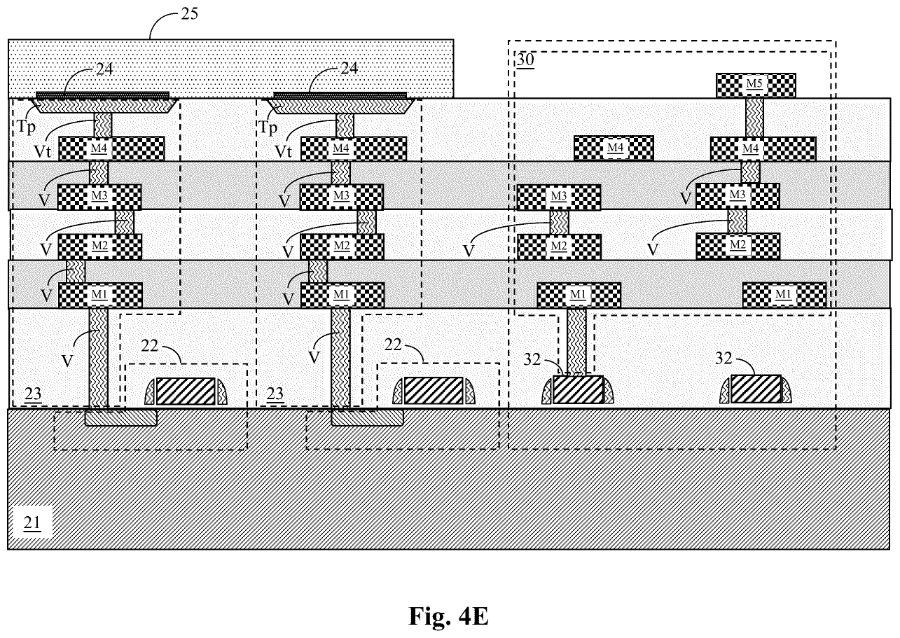

FIGS. 4A-4E show schematic diagrams of process steps for manufacturing an organic photodiode 20 according to one embodiment of the present invention. According to FIGS. 4A-4E, the manufacturing method of the organic photodiode 20 according to the present invention can be explained. As shown in FIG. 4A, first, the device 22 is formed in the substrate 21, and at the same time, at least one semiconductor device 32 of the readout circuit 30 is formed on the substrate 21. After that, the interconnect structure 23 is formed on the substrate 21 and is connected to the device 22. While forming the interconnect structure 23, the interconnect structure 33 is also formed. The interconnect structure 23 includes plural metal layers M1-M4 (shown as four layers in this embodiment, but according to the present invention, the number of metal layers is not limited to four) and plural conduction plugs V. The conduction plugs V are electrically connected to the plural metal layers M1-M4 and the device 22. In addition to the connected portions among the device 22, the plural metal layers M1-M4 and the conduction plugs V, interlayer dielectric layers ILD are provided to insulate between them. Next, for example, by an etching process step, a top plug via Vd is formed.

Next, as shown in FIG. 4B, for example, by an etching process step, the taper plate via Vp is formed. Then, as shown in FIG. 4C, after filling conductive material into the top plug via Vd and the taper plate via Vp, for example, by a chemical mechanical polishing (CMP) process step, a surface on the taper plate Tp is flattened, and the top conduction plug Vt and the taper plate Tp are formed. In this embodiment, for example, the top conduction plug Vt and the taper plate Ip are formed using the dual damascene process as described above. In another embodiment, a single damascene process or a deposition and etching process can also be used to form the top conduction plug Vt and the taper plate Tp. Next, a metal layer M5 is formed on the substrate 21 to form the interconnect structure 33.

Then, as shown in FIG. 4D, the bottom electrode 24 is formed. The bottom electrode 24 is formed above the interconnect structure 23 and is connected to the taper plate Tp of the interconnect structure 23, wherein the bottom electrode 24 is completely formed within the vertical projection region of the upper surface St of the taper plate Tp, and wherein a contact area between the bottom electrode 24 and the taper plate Tp is of a same order of magnitude as a pixel size, while the upper surface St of the taper plate Tp exceeds (i.e., is larger than) the pixel size. Then, as shown in FIG. 4E, the organic layer 25 is formed on the bottom electrode 24 and is connected to the bottom electrode 24.

The present invention has been described in considerable detail having reference to certain preferred embodiments thereof. It should be understood that the description is for illustrative purpose, not for limiting the scope of the present invention. Those skilled in this art can readily conceive variations and modifications within the spirit of the present invention. For example, other process steps or structures which do not affect the primary characteristic of the device, such as a threshold voltage adjustment region, etc., can be added. In view of the foregoing, the spirit of the present invention should cover all such and other modifications and variations, which should be interpreted to fall within the scope of the following claims and their equivalents. An embodiment or a claim of the present invention does not need to achieve all the objectives or advantages of the present invention. The title and abstract are provided for assisting searches but not for limiting the scope of the present invention.

What is claimed is:

1. An organic photodiode, comprising:
a device, which is formed in a substrate;
an interconnect structure, which is formed on the device and is connected to the device;
a bottom electrode, which is formed on the interconnect structure, and is connected to a taper plate of the interconnect structure, wherein the bottom electrode is completely formed within an upper surface of the taper plate, and wherein a contact area between the bottom electrode and the taper plate is of a same order of magnitude as a pixel size, while the upper surface of the taper plate exceeds the pixel size; and
an organic layer, which is formed on the bottom electrode, and is connected to the bottom electrode.

2. The organic photodiode of claim 1, wherein the taper plate is connected to a top conduction plug of the interconnect structure, wherein the top conduction plug is connected to a top metal layer of the interconnect structure, and the taper plate has a lower surface opposite to the upper surface, wherein the upper surface is connected to the bottom electrode and the bottom electrode is located within a vertical projection region of the upper surface, wherein the lower surface is connected to the top conduction plug.

3. The organic photodiode of claim 2, wherein an angle between a taper sidewall of the taper plate and a normal to the lower surface ranges from 0 degrees to 45 degrees.

4. The organic photodiode of claim 1, wherein a material of the bottom electrode includes at least one of the following: titanium nitride, titanium, aluminum, tantalum nitride, tantalum, chromium, silver, and gold.

5. The organic photodiode of claim 1, wherein a readout circuit is additionally formed in the substrate, wherein the readout circuit includes at least one semiconductor device and a readout interconnect structure, and the semiconductor device is electrically connected to the readout interconnect structure, and the readout circuit is coupled to the organic photodiode for reading out a photoelectric signal generated by the organic photodiode.

6. A manufacturing method of an organic photodiode, comprising:
first, forming a device in a substrate;
then, forming an interconnect structure on the device and connected to the device;
then, forming a bottom electrode on the interconnect structure connected to a taper plate of the interconnect structure, wherein the bottom electrode is completely formed within an upper surface of the taper plate, and wherein a contact area between the bottom electrode and the taper plate is of a same order of magnitude as a pixel size, while the upper surface of the taper plate exceeds the pixel size; and
then, forming an organic layer on and connected to the bottom electrode.

7. The manufacturing method of claim 6, wherein the taper plate is connected to a top conduction plug of the interconnect structure, wherein the top conduction plug is connected to a top metal layer of the interconnect structure, and the taper plate has a lower surface opposite to the upper surface, wherein the upper surface is connected to the bottom electrode and the bottom electrode is located within a vertical projection region of the upper surface, wherein the lower surface is connected to the top conduction plug.

8. The manufacturing method of claim 7, wherein an angle between a taper sidewall of the taper plate and a normal to the lower surface ranges from 0 degrees to 45 degrees.

9. The manufacturing method of claim 6, wherein a material of the bottom electrode includes at least one of the following: titanium nitride, titanium, aluminum, tantalum nitride, tantalum, chromium, silver, and gold.

10. The manufacturing method of claim 6, further comprising: forming a readout circuit additionally in the substrate, wherein the readout circuit includes at least one semiconductor device and a readout interconnect structure, and the semiconductor device is are electrically connected to the readout interconnect structure, and the readout circuit is coupled to the organic photodiode for reading out a photoelectric signal generated by the organic photodiode.
